(19) United States
(12) Patent Application Publication
(10) Pub. No.: US 2008/0006937 A1
(43) Pub. Date: Jan. 10, 2008

(54) Solderability Improvement Method for Leaded Semiconductor Package

(75) Inventor: Akira Matsunami, Beppu-city (JP)

Correspondence Address: TEXAS INSTRUMENTS INCORPORATED, P O BOX 655474, M/S 3999, DALLAS, TX, 75265, US

(73) Assignee: Texas Instruments Incorporated, Dallas, TX (US)

(21) Appl. No.: 11/426,157

(22) Filed: Jun. 23, 2006

(51) Int. Cl. H01L 23/48; H01L 23/52; H01L 29/40

(52) U.S. Cl. 257/734

(57) ABSTRACT

A microelectronic device package that includes a microelectronic device encapsulated within a packaging material. The microelectronic device package also includes a lead attached to a portion of the microelectronic device extending through the packaging material. The lead has a break portion and a non-break portion on a tip of the lead.

### CROSS-REFERENCE TO RELATED APPLICATIONS

Not applicable

### STATEMENT REGARDING FEDERALLY SPONSORED RESEARCH OR DEVELOPMENT

Not applicable.

### REFERENCE TO A MICROFICHE APPENDIX

Not applicable.

### BACKGROUND

Assembly of microelectronic devices into packages suitable for use in electronic products includes numerous challenges. Generally, product material begins an assembly process in the form of processed semiconductor wafers. The processed wafers include a plurality of microelectronic devices, which are cut into individual devices and are further processed into packaged microelectronic devices to form a resulting packaged device suitable for use in a myriad of electronic-based products. During the final assembly steps, the individual devices may be mounted onto one or more assembly structures that provide electrical routing. The assembly structures include electrical leads that are used for attachment of the final assembled microelectronic device package onto other microelectronic device package(s), electrical boards such as a printed circuit board (PCB), or other assemblies employed in electronic-based products. The configuration of the package and lead structure present challenges in the design and manufacturing of electronic products.

In today's electronic-based products, there exists a myriad of microelectronic device packages. The packaged microelectronic devices may be assembled to form products such as mobile phones, computers, televisions, or other products. The microelectronic device packages are assembled together in electronic devices to execute various functions of the electronic device and may each include various functions. For example, one microelectronic device package may include a digital signal processor (DSP) while another microelectronic device package may include memory, a graphics processor, or other devices. These packages conform to standards established by industry associations such as the Joint Electron Device Engineering Council (JEDEC). The standards help to provide guidelines for reliability of microelectronic device packages. New microelectronic device packages are constantly being created primarily since there is a constant need to reduce the footprint of the package in products such as mobile phones, or other mobile electronic devices. As the need for greater computational processing power and more functionality arises, so does the complexity of the packaging of the devices used to form an electronic-based product. Moreover, the assembly of microelectronic devices into reliable components becomes a challenge, and therefore measures to simplify assembly processes are continually needed.

During final assembly steps, individual microelectronic devices or “die” are mounted onto lead frame assemblies that provide electrical routing of the die to other electrical devices. The lead frame assemblies may be processed through an epoxy-molding step to encapsulate each die on the lead frame assembly. Finally, the lead frame assembly is cut or trimmed to form individually packaged microelectronic devices.

### SUMMARY

The present disclosure provides a microelectronic device package including a microelectronic device encapsulated within a packaging material. The microelectronic device package also includes a lead attached to a portion of the microelectronic device extending through the packaging material. The lead has a break portion and a non-break portion on a tip of the lead.

In an embodiment, a method is provided for manufacturing a microelectronic device package. The method includes providing a microelectronic device package lead frame having a plurality of grooves located adjacent to at least one of a plurality of leads associated with a die pad that supports a microelectronic device. The method also includes connecting a portion of the microelectronic device to at least one of the leads, and encapsulating the microelectronic device, the die pad, and at least a portion of the leads. The method further includes trimming a portion of the microelectronic device package lead frame adjacent to the grooves to provide a break located on a portion of each of the leads.

In another embodiment a printed circuit board is provided. The printed circuit board includes a microelectronic device encapsulated within a packaging material. The printed circuit board also includes a lead attached to a portion of the microelectronic device extending through the packaging material. The lead has a break portion and a non-break portion on a tip of the lead.

The present disclosure reduces the surface area of the break (i.e., the exposed base material) and increases the solder wettability of the edge of the lead by providing pre-fabricated grooves adjacent to the leads in the lead frame assembly. One advantage of present disclosure is that improved solder wettability of the edge results in a more reliable solder joint between the leads and a substrate, such as the printed circuit board. These and other features and advantages will be more clearly understood from the following detailed description taken in conjunction with the accompanying drawings and claims.

### BRIEF DESCRIPTION OF THE DRAWINGS

For a more complete understanding of the present disclosure and the advantages thereof, reference is now made to the following brief description, taken in connection with the accompanying drawings and detailed description, wherein like reference numerals represent like parts.

FIG. 1a illustrates one embodiment of a microelectronic device package according to aspects of the present disclosure.

FIG. 1a1 is an exploded view of a portion of a lead of the microelectronic device package shown in FIG. 1a.

FIG. 1b illustrates another embodiment of a microelectronic device package according to aspects of the present disclosure.

FIG. 1b1 is an exploded view of a portion of a lead of the microelectronic device package shown in FIG. 1b.

FIG. 1c illustrates a cross-sectional view of one embodiment of the leads of a microelectronic device package according to aspects of the present disclosure.

FIG. 2 is a flow diagram of a process for manufacturing a microelectronic device package according to one embodiment of the present disclosure.

FIGS. 3a through 3g are cross-sectional views of manufacturing steps for forming a microelectronic device package according to one embodiment of the present disclosure.

FIG. 4 illustrates a top view of an exemplary general-purpose printed circuit board (PCB) suitable for implementing the several embodiments of the present disclosure.

### DETAILED DESCRIPTION

It should be understood at the outset that although an exemplary implementation of one embodiment of the present disclosure is illustrated below, the present system may be implemented using any number of techniques, whether currently known or in existence. The present disclosure should in no way be limited to the exemplary implementations, drawings, and techniques illustrated below, including the exemplary design and implementation illustrated and described herein.

Accordingly, the present disclosure contemplates a microelectronic device package having one or more leads each with a small break located on the edge of the lead, the break consisting of less than the total area of the edge of the lead. The break is a result of a trimming process (i.e., a process of cutting the tip of the leads) of a lead frame assembly that occurs during final steps of the assembly of the microelectronic device package. The dimensions of the break are determined by a groove adjacent to each lead in the lead frame assembly. The lead frame assembly generally includes a base material, such as copper and may include one or more protective layers that may include, for example, nickel and palladium, or tin and bismuth disposed on the base material. The protective layer promotes solder wettability of the leads of the packaged microelectronic device. Solder wettability is defined as the ability of the solder to dissolve and penetrate the surface of the leads, wherein the molecules of the solder and the lead material blend to form a new alloy. The break exposes the base material of the lead frame assembly. The base material is difficult to solder since oxides and other contaminates readily form on the surface of base material when exposed to air. Applying solder to the base material surface with oxidized or other contaminated surfaces results in un-reliable joints between the leads and a substrate, such as a printed circuit board (PCB). Inconsistent soldering of the leads to the substrate often results in non-functional packaged microelectronic devices, reduced assembly cycle time, and degradation of product reliability. Moreover, the embodiments of the present disclosure provide a microelectronic device package and method of manufacturing that reduces the surface area of the break (i.e., the exposed base material) and increases the solder wettability of the edge of the lead by providing pre-fabricated grooves adjacent to the leads in the lead frame assembly.

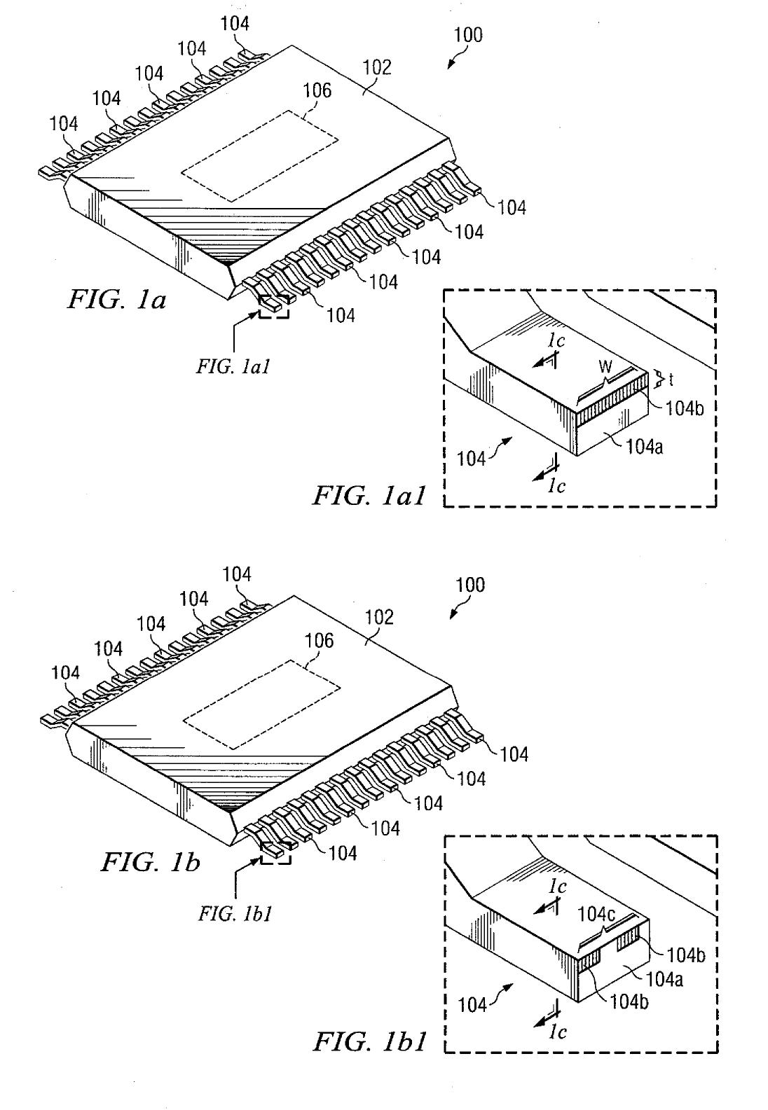

Turning now to FIGS. 1a and 1a1, illustrated are leads 104 attached to a microelectronic device 106 encapsulated in a packaging material 102. The microelectronic device package 100 electrically connects the microelectronic device 106 through the leads 104 to a myriad of electronic components The microelectronic device 106 may include one device or may include multiple devices in some embodiments. The microelectronic device package 100 includes a packaging material 102 for encapsulating and protecting one or more microelectronic device 106, and a portion of the leads 104 attached to the microelectronic device 106.

In an embodiment, the microelectronic device package 100 may include anyone of a number of different package types that are commonly employed. For example, the microelectronic device package 100 may include a small outline package (SOP), a small shrink outline package (SSOP), a thin shrink small outline package (TSSOP), a thin quad flat pack (TQFP), a low profile quad flat package (LQFP), and other forms of device packages. Of course it is to be understood, the microelectronic device package 100 may include other packages presently employed and other future developed device packages.

The packaging material 102 protects the microelectronic device 106 and a portion of the leads 104. The packaging material 102 may be formed using low stress molding compounds with high thermal conductivity. The packaging material 102 may be formed by thermal compression of epoxy to form a mold encapsulating the microelectronic device 106. The packaging material 102 may include materials such as epoxy, ceramic or other material adapted for protecting the microelectronic device 106. In an embodiment, the packaging material 102 may include epoxy resins, phenolic hardeners, silicas, catalysts, pigments, mold release agents, or other compounds. Alternatively, the packaging material 102 may include multiple parts, such as a ceramic header and a top cap attached over the header to protect a mounted device.

The leads 104 extend from the packaging material 102 and provide electrical routing from the microelectronic device 106 situated inside of the packaging material 102. As seen in FIG. 1c, the leads 104 may include a conductive base material 104d such as copper, and may include one or more protective layer 104e having nickel and palladium, or tin and bismuth, or other materials. The leads 104 may be attached to a PCB substrate by solder, which may include a lead/tin or a lead-free material comprising tin, copper, and silver. The leads 104 may be formed from a larger piece of conductive material referred to as a lead frame or lead frame assembly, which includes a plurality of die pads and associated leads for mounting and forming a plurality of microelectronic device packages. The leads 104 are formed when the lead frame is cut or trimmed.

In an embodiment, the leads 104 may each include a break 104b and a non-break 104a portions located on the tip 105 or side of the leads 104. The non-break 104a may be part of a groove that was previously cut or formed in the lead frame 104, which will be discussed in greater detail below. The break 104b is formed during the trimming of the lead frame where the leads 104 are separated from unused portions of the lead frame. Although breaks 104b are shown in FIGS. 1a1 and 1b1 as generally flat areas, the break 104b area will typically be jagged or uneven and extend from the tip 105, similar to that shown in FIG. 1c. In an embodiment, the break 104b may be any size such that it comprises less than the entire tip 105 of the lead 104. The tip 105 may be defined as the side or surface that includes at least some of the break 104b and at least some of the non-break 104a.

The non-break 104a includes the base material 104d and the protective layer 104e that may include nickel and palladium, or tin and bismuth as depicted in the cross-section of FIG. 1c. The break 104b may be located at the tip 105 or along a side of each of the leads 104. In some embodiments, the break 104b may comprise greater or lesser portions of the tip 105 than the non-break 104a. In other embodiments, the break 104b may also comprise half of the tip 105 and the non-break 104a may comprise the other half of the tip 105 of the lead 104. In some embodiments, the break 104b may include a width w from about 0.01 mm to about 1 mm, and a thickness t from about 0.1 mm to about 0.25 mm. The width w and thickness t of the break 104b are determined by the size or area of the non-break 104a of the leads 104. Preferably, the width w and thickness t of the break 104b are reduced (or perhaps minimized), while the non-break 104a is increased (or perhaps maximized).

Of course, the break 104b is not to be limited to the embodiment depicted in FIG. 1a, and therefore may include other shapes or patterns such as for example a stitch 104c as depicted in FIGS. 1b and 1b1. The stitch 104c reduces the overall size or area of the break 104b on the leads 104, and therefore increases the size or surface area of non-break 104a portion. In this manner, greater solder wettability of the surface of the leads 104 is provided after trimming the lead frame to form the microelectronic device package 100. In some embodiments, the break 104b may also include other patterns or shapes that may be circular and or other shapes determined by the design of the lead frame.

During the soldering process, the micro-electronic device package 100 is attached to the substrate such as the PCB. The break 104b formed after trimming of the lead frame exposes the base material 104d of the leads 104, which may include copper. The size or surface area of the break 104b is determined by pre-fabricated grooves in the lead frame assembly. The protective layer 104e disposed over the leads 104 promotes solder wettability and decreases the time needed to solder the leads 104 to a substrate, such as a PCB. Moreover, reducing the surface area of the break 104b by increasing the depth of the grooves in the lead frame assembly increases the surface area of the non-break 104a portion. Increasing the surface area of the non-break 104a provides greater solder wettability, and therefore provides a more reliable solder joint between the leads 104 and the substrate such as the PCB. High solder joint reliability between the leads 104 and the substrate is achieved by increasing the surface area of the non-break 104a (i.e., solder wettable area), and by reducing the surface of the break 104b (i.e., non-solder wettable area) on the leads 104.

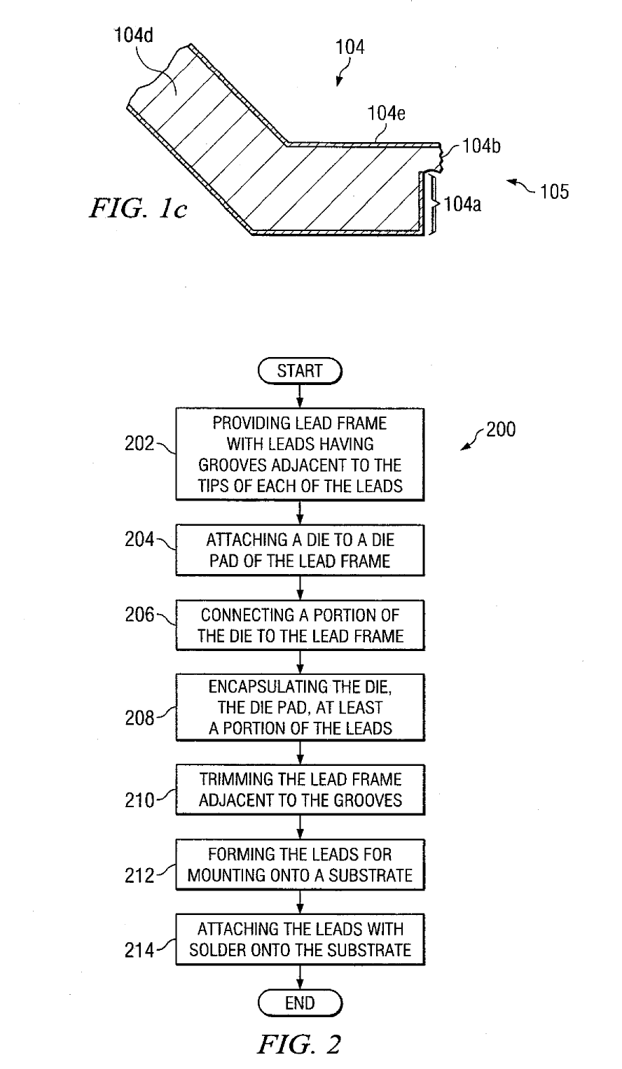

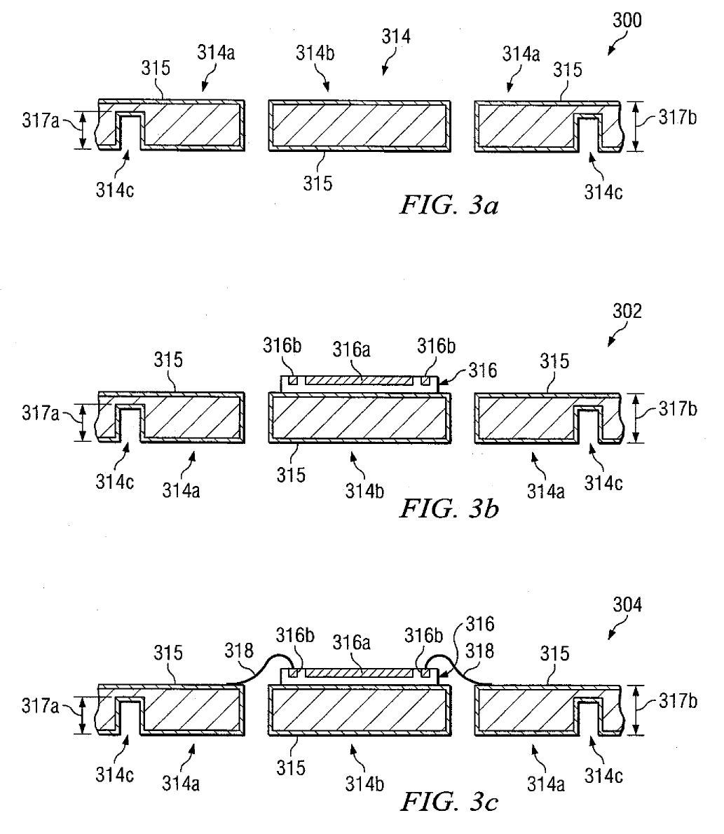

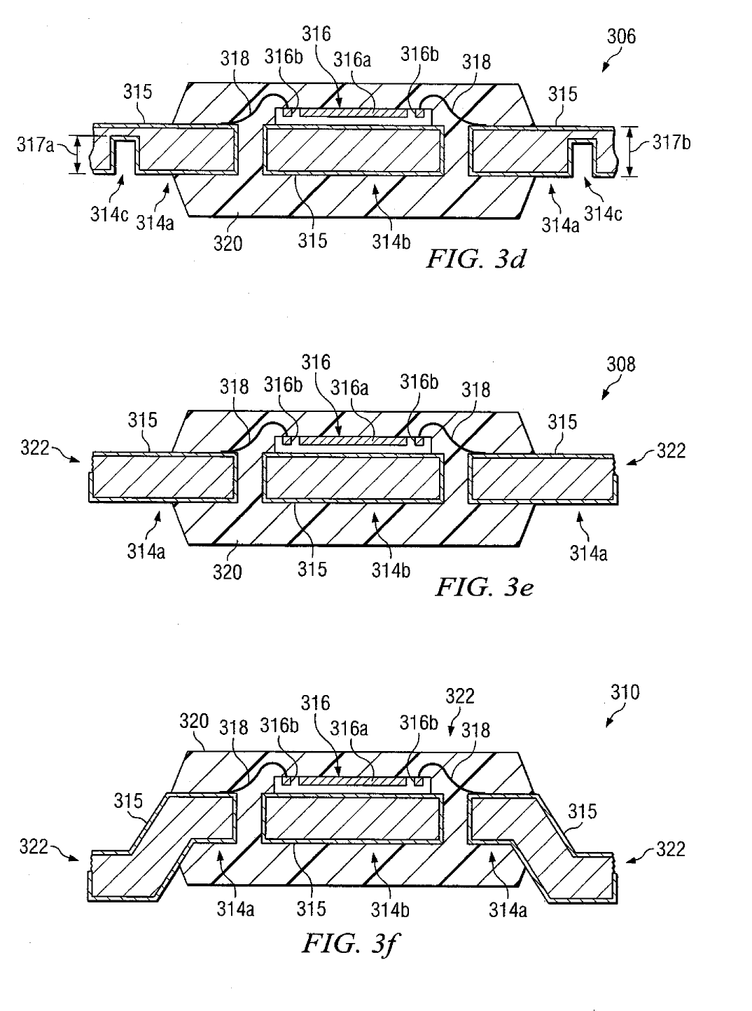

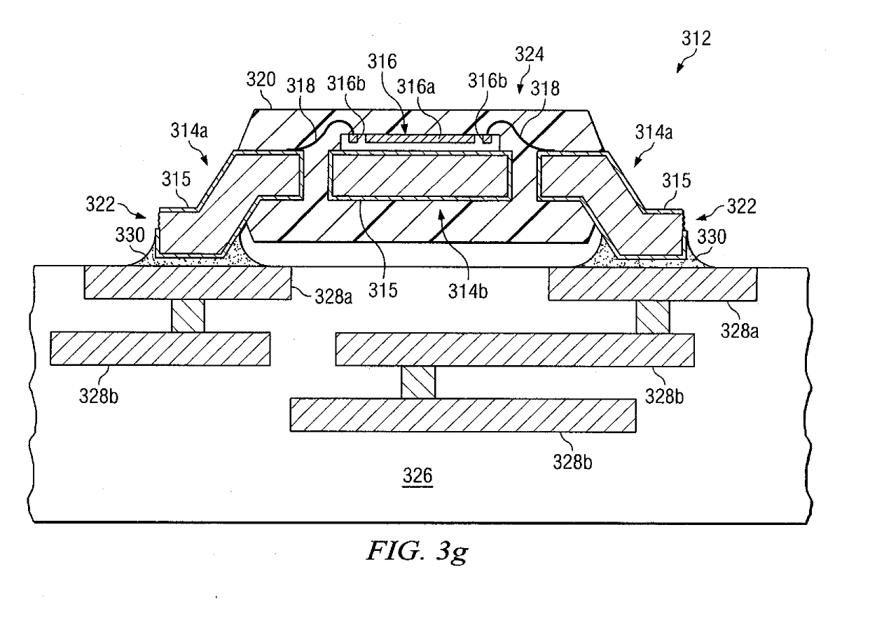

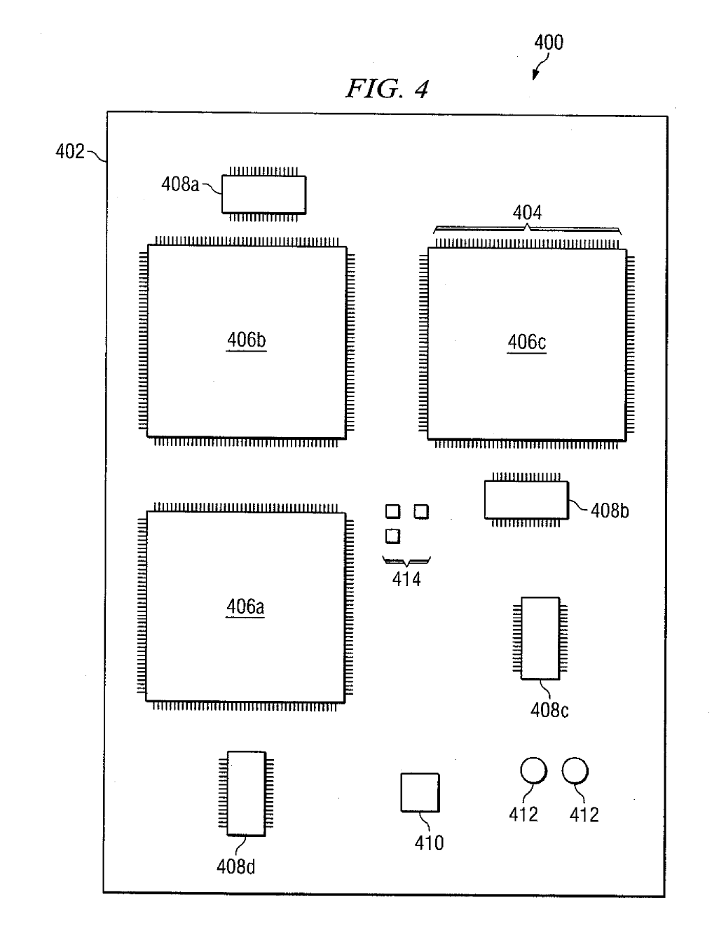

Referring to FIG. 2 with reference to FIG. 3a through FIG. 3g, cross-sectional views 300, 302, 304, 306, 308, 310, and 312 depict an embodiment of the microelectronic device 100. The views 300, 302, 304, 306, 308, 310, and 312 illustrate assembly steps of a process 200 for forming and mounting the microelectronic device 100 to the substrate, such as the PCB.

Turning now to FIG. 2, in an embodiment, a flow diagram depicts the process 200 for forming the microelectronic device package 100. In block 202 with reference to FIG. 3a, a lead frame 314 having lead frame leads 314a; die pad 314b, and grooves 314c is provided. The lead frame 314 includes the base material 104d and may include a protective layer 315 that may include a first layer of nickel and a second layer palladium, or tin and bismuth. In some embodiments, the protective layer 315 may include gold or other metals. The protective layer 315 may be formed by electroless plating or electroplating. The lead frame 314 may be rigid or flexible and may be disposed on an insulator. The lead frame 314 may also include a long single piece that may include a plurality of the die pads 314b and associated lead frame leads 314a. The grooves 314c may be formed by etching, stamping, or coining the portion the lead frame 314. Alternatively, the grooves 314c may be formed by mechanical milling, chemical etch, or other methods. The grooves 314c may be included in the lead frame 314 and positioned between each of the lead frame leads 314a.

In an embodiment, the grooves 314c determine the surface area of the non-break 104a and the surface area of the break 104b. The depth 317a of the grooves 314c may vary, but will typically be less than the thickness 317b of the lead frame 314. Where a stitch pattern or other configuration is used, such as discussed above with reference to FIG. 1b, portions of the groove 314c may extend through the entire thickness 317b of the lead frame 314. The depth 317a of the grooves 314c determines the dimensions of the break 104b and the non-break 104a. For example, a SOP package may include the leads from a lead frame having a thickness 317b of about 0.5 mm, and the depth 317a of the grooves 314c may be about 0.25 mm.

In block 204 with reference to FIG. 3b, a die 316 is attached to the die pad 314b of the lead frame 314. The die 316 may be attached to the die pad 314b by epoxy and may include for example a silver epoxy disposed on the die pad 314b prior to the attachment of the die 316. The die 316 includes a semiconductor material such as silicon processed by multiple steps to form the microelectronic device 106. In an embodiment, the die 316 includes a circuitry portion 316a or device portion and associated bond pads 316b. The circuitry portion 316a may include an integrated circuit having a myriad of N-type or P-type, or both, metal oxide semiconductor (MOS) devices. The circuitry portion 316a may also include other devices and structures such as a micro-electro-mechanical (MEMS) device. In some embodiments, the die 316 may include multiple devices stacked together. The bond pads 316b may be located on an outer portion of the die 316 or situated near the center portion of the die 316 in some embodiments.

In bock 206 with reference to FIG. 3c, the bond pads 316b of the die 316 and the lead frame leads 314a are attached. In an embodiment, the bond pads 316b may be attached by wires 318a to the lead frame leads 314a. The wires 318 may be formed by wire bonding and may include materials such as gold, aluminum, copper, or other materials. Of course, the bond pads 316b may be attached to the lead frame leads 314a by other process that may include direct solder to the bond pads 316b and lead frame leads 314a by powdered solder dip, wave soldering, solder ball bumping, or other methods.

In block 208 with reference to FIG. 3d, the die pad 314b, and the lead frame leads 314a are encapsulated within a packaging material 320. A mold or mold press may be employed to form melted epoxy used to form the packaging material 320. The lead frame 314 may be placed into a mold to form a plurality of molded die. The packaging material 320 may be formed by thermal compression of epoxy to form a mold encapsulating the die 316. The packaging material 320 may include materials such as epoxy, ceramic, or other material adapted for protecting the die 316. In an embodiment, the packaging material 320 may include epoxy resins, phenolic hardeners, silicas, catalysts, pigments, mold release agents, or other compounds. Alternatively, the packaging material 320 may include multiple parts, such as a ceramic header and a top cap attached over the header to protect a mounted device.

In block 210 with reference to FIG. 3e, the lead frame leads 314a are cut at the grooves 314c. The grooves 314c may be punched out with a mechanical press or other cutting tool. A break 322 is formed where the lead frames leads 314a are trimmed or “cut” at the grooves 314c. The break 322 exposes the base material of the lead frame leads 314a. The remaining portion of the lead frame leads 314a and associated surface of the grooves 314c includes the protective layer 315 after the trimming process. In an embodiment, the break 322 may be substantially similar to the break 104b of FIG. 1.

In block 212 with reference to FIG. 3f, the lead frame leads 314a are bent or formed to create a packaged microelectronic device 324. The 314a may be bent or formed by a mechanical press or other tool.

In block 214 with reference to FIG. 3g, the lead frame leads 314a are attached to a substrate 326 with solder 330. The lead frame leads 314a may be attached to the substrate 326, such as a PCB by applying solder paste to selected interconnect sites 328a and subsequently heating (i.e., solder re-flow) to melt the solder paste to form solder joints 330 between the lead frame leads 314a and the interconnect sites 328a. The substrate 326 includes one or more conductive traces or interconnects 328b connected to the interconnect sites 328a. The interconnects 328b may include copper or gold, and provide routing of electrical signals to and from the leads 314a. The interconnects 328b may include multiple levels of routing, where each level is situated between a layer of insulation for example The solder paste may include solder powder and flux. For example, the solder powder may include a lead-free solder such as tin, silver, and copper compound. The flux may include a fluid having constituents such as an adhesion-imparting agent for cleaning of the surface of the protective layer 315, a thixotropic agent to provide solder powder separation, a solvent for paste formation, and an activator for removing oxides off the surface of the protective layer 315. The solder joints 330 include solder that melts and wets the surface of the lead frame leads 314a up to the break 322. In an embodiment, the break 322 may be located immediate adjacent to the surface of the substrate 326. The surface area of the break 322 may be formed to be as small as possible by increasing the depth 317a of the grooves 314c. The outer surface 314a increases the available solder wettable surface area of the lead frame leads 314. Moreover, the reliability of the solder joint 330 is improved since the interfacial area of the solder joint 330 increases by increasing the size of the outer surface 314a. The outer surface 314a may be increased by providing the depth 317a of the grooves 314c to be less than the thickness 317b of the lead frame 314. The process then ends.

The packaged microelectronic device 100 described above may be employed on any general-purpose substrate having electrical contacts and interconnects suitable for integrating a myriad of electronic devices and components. FIG. 4 illustrates a typical, general-purpose printed circuit board (PCB) 400 suitable for implementing one or more embodiments disclosed herein. The PCB 400 includes a substrate 402, packaged devices 406a, 406b, 406c, 408a, 408b, 408c, 408d, and 410, and electrical components 412, and 414. The substrate 402 may be rigid or flexible and may include multiple layers of insulative material and conductive interconnects. The packaged devices 406a, 406b, 406c, 408a, 408b, 408c, 408d, and 410 each include leads 404 that are attached to the substrate 402 by for example solder. Each of leads 404 includes the break 104b as depicted in the microelectronic device 100 of FIGS. 1a-b. In some embodiments, the packaged devices 406a, 406b, and 406c may include a LQFP package, the packaged devices 408a, 408b, 408c, and 408d may include TSSOP package, and the packaged device 410 may include a ball grid array (BGA) packaged device. Of course, the packaged devices 406a, 406b, 406c, 408a, 408b, 408c, 408d, and 410 may include other forms of packaging widely employed, such as J-lead small outline package (SOJ), plastic leaded chip carrier (PLCC), plastic dual in-line package (PDIP), or other forms of packaging. The substrate 402 may also include the electrical components 412 in the form of resistors, and the components 414 may include capacitors. The electrical components 412 may also include other components such as inductors, thyristors or fuses (i.e., over-current or over-voltage protection devices), or other small component devices.

In an embodiment, the PCB 400 may be employed in, for example, a mobile electronic device such as a mobile phone or personnel data assistant (PDA). In other embodiments, the PCB 400 may be employed in electrical components employed in automotive vehicles where the PCB 400 may be subjected to a significant amount of thermal stress. The microelectronic device package 100 and process 200 provide a reliable solder joint between the leads 404 and the substrate 402, and therefore provide a reliable product able to withstand significant thermal stress. Of course, the PCB 400 or the microelectronic device package 100 may be employed in other electronic devices such as computers, networking equipment such as wireless routers, mobile audio devices, or other electronic devices.

While several embodiments have been provided in the present disclosure, it should be understood that the disclosed systems and methods may be embodied in many other specific forms without departing from the spirit or scope of the present disclosure. The present examples are to be considered as illustrative and not restrictive, and the intention is not to be limited to the details given herein, but may be modified within the scope of the appended claims along with their full scope of equivalents. For example, the various elements or components may be combined or integrated in another system or certain features may be omitted, or not implemented.

Also, techniques, systems, subsystems and methods described and illustrated in the various embodiments as discrete or separate may be combined or integrated with other systems, modules, techniques, or methods without departing from the scope of the present disclosure. Other examples of changes, substitutions, and alterations are ascertainable by one skilled in the art and could be made without departing from the spirit and scope disclosed herein.

What is claimed is:

1. A microelectronic device package, comprising:
a microelectronic device encapsulated within a packaging material; and
a lead attached to a portion of the microelectronic device extending through the packaging material, the lead having a break portion and a non-break portion on a tip of the lead.

2. The microelectronic device package of claim 1, wherein the break exposes at least a portion of an underlying material of the lead.

3. The microelectronic device package of claim 1, wherein the break portion comprises less of the tip than the non-break portion.

4. The microelectronic device package of claim 1, wherein the break is located at the tip of the lead and comprising no more than about half an area of the tip.

5. The microelectronic device package of claim 1, wherein the break comprises a stitch located at the tip of the lead.

6. The microelectronic device package of claim 1, wherein the break comprises a width from about 0.01 mm to about 1 mm, and a thickness from about 0.1 mm to about 0.25 mm.

7. The microelectronic device package of claim 1, wherein the lead further comprises a base material and a protective layer.

8. The microelectronic device package of claim 7, wherein the base material comprises copper.

9. The microelectronic device package of claim 7, wherein the protective layer comprises a first layer comprising nickel and a second layer disposed over the first layer comprising palladium.

10. The microelectronic device package of claim 7, wherein the protective layer comprises a material including tin and bismuth.

11. The microelectronic device package of claim 7, wherein the protective layer comprises gold.

12. The microelectronic device package of claim 1, wherein the microelectronic package is a small outline package (SOP).

13. The microelectronic device package of claim 1, wherein the microelectronic package is a quad flat package (QFP).

14. A method for manufacturing a microelectronic device package, comprising:
providing a microelectronic device package lead frame having a groove located adjacent to at least one of a plurality of leads that support a microelectronic device;
connecting a portion of the microelectronic device to at least one of the leads;
encapsulating the microelectronic device and at least a portion of the leads; and
trimming a portion of the microelectronic device package lead frame adjacent to the groove to provide a break located on a portion of each of the leads.

15. The method of claim 14, wherein the trimming a portion of the microelectronic device package lead frame occurs at the grooves.

16. The method of claim 14, wherein the plurality of grooves have a depth less than the thickness of the microelectronic device package lead frame.

17. A printed circuit board (PCB), comprising:
a substrate having a plurality of interconnects; and
at least one microelectronic device package having at least one lead attached to the substrate and at least one of the interconnects, the at least one lead having a break portion and a non-break portion on a side of the lead.

18. The PCB of claim 17, wherein the break is located on the edge of the lead and is adjacent to the surface of the substrate.

19. The PCB of claim 17, wherein the break is located on a tip of the lead and is adjacent to a groove that is adjacent to a solder joint.

20. The PCB of claim 17, wherein the microelectronic device package is a quad flat package (QFP).
